(19) United States
(12) Patent Application Publication
(10) Pub. No.: US 2024/0248399 A1
(43) Pub. Date: Jul. 25, 2024

(54) PHOTOSENSITIVE PASTE AND METHOD FOR PRODUCING ELECTRONIC COMPONENTS

(71) Applicant: Murata Manufacturing Co., Ltd., Kyoto (JP)

(72) Inventor: Rikiya SANO, Nagaokakyo-shi (JP)

(73) Assignee: Murata Manufacturing Co., Ltd., Kyoto (JP)

(21) Appl. No.: 18/627,130

(22) Filed: Apr. 4, 2024

Related U.S. Application Data
(63) Continuation of application No. PCT/JP2022/031972, filed on Aug. 25, 2022.

(30) Foreign Application Priority Data
Oct. 5, 2021 (JP) 2021-163960

(51) Int. Cl. G03F 7/004; C03C 3/091; C03C 8/02; C03C 8/14; H01B 1/22

(52) U.S. Cl. CPC G03F 7/0048; C03C 3/091; C03C 8/02; C03C 8/14; H01B 1/22; C03C 2205/00

(57) ABSTRACT

A photosensitive paste contains an inorganic powder containing an element that forms a polyvalent metal ion; an alkali-soluble polymer; a photosensitive monomer, and a photoinitiator. A dispersion of 1 wt % of the inorganic powder containing an element that forms a polyvalent metal ion in pure water has a conductivity of 170 mS/m or less at 10 minutes after dispersion.

### CROSS-REFERENCE TO RELATED APPLICATIONS

This application claims benefit of priority to International Patent Application No. PCT/JP2022/031972, filed Aug. 25, 2022, and to Japanese Patent Application No. 2021-163960, filed Oct. 5, 2021, the entire contents of each are incorporated herein by reference.

### BACKGROUND

### Technical Field

The present disclosure relates to a photosensitive paste and a method of producing electronic components.

### Background Art

There is a known method in which a photosensitive paste containing an inorganic component and an organic component is used to form insulation layers and wiring conductors of electronic components and printed wiring boards, for example.

For example, WO 2018/037729 discloses a photosensitive glass paste containing an inorganic component containing a glass powder and a ceramic filler and a photosensitive organic component. Examples of the photosensitive organic component include alkali-soluble polymers, photosensitive monomers, photopolymerization initiators, and solvents. Examples of the alkali-soluble polymers include polymers having a carboxy group in a side chain thereof, such as a copolymer of methacrylic acid and methyl methacrylate.

### SUMMARY

The glass powder used in the photosensitive glass paste of WO 2018/037729 contains alkaline earth metal elements and lanthanoids. When such a glass powder is kneaded with a polymer having an acidic functional group such as a carboxy group to form a paste, polyvalent metal ions of alkaline earth metal elements or the like present on the surface of the glass powder and polyvalent metal ions of alkaline earth metal elements or the like leaching from the glass powder into the paste are adsorbed onto the acidic functional groups in the polymer, and these ions are crosslinked with the functional groups. The crosslinking bonding between the glass powder, which is an inorganic powder, and the polymer as described above causes thickening (gelation) of the resulting paste.

As a measure to prevent adsorption of polyvalent metal ions onto acidic functional groups in a polymer, WO 2012/067016 discloses a conductive paste containing a polycarboxylic acid and a chelating agent, in addition to a photosensitive organic component containing copper particles. According to WO 2012/067016, when low molecular weight organic acids such as a polycarboxylic acid and a chelating agent are adsorbed onto the surface of copper particles (inorganic powder) and cover the surface, it makes it possible to prevent adsorption of the copper particles onto the polymer and thickening of the conductive paste. However, since the low molecular weight organic acid to be added is a substance that dissolves in the paste solvent, leaching of copper ions into the paste cannot be prevented.

In the case of a paste for photolithography, leaching of polyvalent metal ions of alkaline earth metal elements, copper, and the like into the paste causes salt formation of the acidic functional groups in the polymer with the polyvalent metal ions even when the polymer is in paste form, which reduces the solubility of the polymer in an alkaline developer. Further, the polyvalent metal ions leached into the paste react in the dark with polymerizable monomers and oligomers, which causes thickening (gelation) of the paste. In the conductive paste of WO 2012/067016, the insolubilization in the alkaline developer and the dark reaction with polymerizable monomers cannot be prevented, so that it is impossible to prevent gelation and impart photolithographic properties at the same time.

The present disclosure provides a photosensitive paste which is prevented from becoming thick and insoluble in an alkaline developer due to polyvalent metal ions. The present disclosure also aims to provide a method of producing electronic components, the method including forming an insulation layer with the photosensitive paste. The present disclosure also aims to provide a method of producing electronic components, the method including forming a conductor layer with the photosensitive paste.

The photosensitive paste of the present disclosure contains an inorganic powder containing an element that forms a polyvalent metal ion; an alkali-soluble polymer; a photosensitive monomer; and a photoinitiator, wherein a dispersion of 1 wt % of the inorganic powder containing an element that forms a polyvalent metal ion in pure water has a conductivity of 170 mS/m or less at 10 minutes after dispersion.

A method of producing electronic components of the present disclosure includes forming an insulation layer with an insulation paste; and forming a conductor layer with a conductor paste on the insulation layer.

In a first method of producing electronic components of the present disclosure, the insulation paste is the photosensitive paste of the present disclosure.

In a second method of producing electronic components of the present disclosure, the conductor paste is the photosensitive paste of the present disclosure.

The present disclosure can provide a photosensitive paste which is prevented from becoming thick and insoluble in an alkaline developer due to polyvalent metal ions.

### BRIEF DESCRIPTION OF THE DRAWINGS

FIG. 1 is a graph showing the conductivity of a dispersion of 1 wt % of an inorganic powder in pure water;

FIG. 2 is a graph showing measurement results of the Brookfield viscosity of photosensitive pastes produced in Examples;

FIG. 3A is a photo showing planar shapes of various patterns formed by photolithography with a photosensitive paste containing glass frit coated with 3 wt % tetraethoxysilane;

FIG. 3B is a photo showing a cross-sectional shape of a portion of the patterns in FIG. 3A;

FIG. 4 is a photo showing planar shapes of various patterns formed by photolithography with a photosensitive paste containing glass frit coated with 3 wt % tetraethoxysilane and polyvinylpyrrolidone;

FIG. 5 is a photo showing planar shapes of various patterns formed by photolithography with a photosensitive paste containing glass frit coated with 6 wt % tetraethoxysilane and polyvinylpyrrolidone;

FIG. 6A is a photo showing planar shapes of various patterns formed by photolithography with a photosensitive paste containing glass frit having a surface coated with malonic acid; and

FIG. 6B is a photo showing a cross-sectional shape of a portion of the patterns in FIG. 6A.

### DETAILED DESCRIPTION

Hereinafter, the photosensitive paste of the present disclosure, the first method of producing electronic components of the present disclosure, and the second method of producing electronic components of the present disclosure are described. The present disclosure is not limited to the following preferred embodiments and may be suitably modified without departing from the gist of the present disclosure. Combinations of two or more preferred features described in the following preferred embodiments are also within the scope of the present disclosure.

### <Photosensitive Paste>

The photosensitive paste of the present disclosure contains an inorganic powder containing an element that forms a polyvalent metal ion; an alkali-soluble polymer; a photosensitive monomer; and a photoinitiator. The photosensitive paste of the present disclosure contains a photosensitive insulation paste for use in forming an insulation layer or a photosensitive conductor paste for use in forming a conductor layer. First, a description is given on the case where the photosensitive paste of the present disclosure is a photosensitive insulation paste.

### Photosensitive Insulation Paste

(Inorganic Powder Containing Element that Forms Polyvalent Metal Ion)

The “element that forms a polyvalent metal ion” in the inorganic powder containing an element that forms a polyvalent metal ion is not limited as long as it is an element that forms a divalent or higher metal ion. Examples include alkaline earth metals and metal elements in groups 3 to 14. In the present disclosure, preferably, the element that forms a polyvalent metal ion is at least one element selected from the group consisting of alkaline earth metals, lanthanoids, Ni, Cu, Pd, Al, Ti, Zr, Zn, Ga, Pb, Nb, Fe, Co, and V.

In the photosensitive insulation paste of the present disclosure, preferably, the inorganic powder containing an element that forms a polyvalent metal ion is an insulator mainly containing a metal oxide crystal or an amorphous insulator mainly containing SiO₂. A high-strength insulator material can be obtained by firing a photosensitive paste containing an insulator mainly containing a metal oxide crystal or an amorphous insulator mainly containing SiO₂.

Examples of the insulator mainly containing a metal oxide crystal include TiO₂, BaTiO, and NiO. Examples of the amorphous insulator mainly containing SiO₂ include SiO₂—B₂O₃—Na₂O—K₂O—CaO—Al₂O₃-based glass powder and SiO₂—B₂O₃—Na₂O—K₂O—Al₂O₃-based glass powder.

In the photosensitive insulation paste of the present disclosure, preferably, the inorganic powder containing an element that forms a polyvalent metal ion is a glass powder having a crystallization point, because a higher-strength insulator material can be obtained by firing a photosensitive paste containing a glass powder having a crystallization point. Examples of the glass powder having a crystallization point include, in addition to SiO₂, glass powders containing B₂O₃, CaO, ZnO, BizO3, BaO, MgO, La₂O₃, Na₂O, K₂O and/or Al₂O₃ or the like, such as SiO₂—B₂O₃—Al₂O₃—CaO-based glass powder, SiO₂—B₂O₃—BaO—ZnO—Al₂O₃—MgO—La₂O₃-based glass powder, and SiO₂—B₂O₃—CaO—Al₂O₃—Na₂O—K₂O-based glass powder.

Preferably, the glass powder having a crystallization point is one whose softening point (Ts) and crystallization point (Tc) are adjusted according to firing conditions. For example, in the case of firing at 850° C. or higher and 950° C. or lower (i.e., from 850° C. to 950° C.), use of a glass powder or the like having a Ts of 800° C. and a Tc of 890° C. is preferred. The glass powder having a crystallization point may have any composition without being limited to the above examples, as long as it is a glass powder having similar Ts and Tc.

Any of these inorganic powders containing an element that forms a polyvalent metal ion may be used alone or in combination of two or more.

In the photosensitive insulation paste of the present disclosure, a dispersion of 1 wt % of the inorganic powder containing an element that forms a polyvalent metal ion in pure water has a conductivity of 170 mS/m or less at 10 minutes after dispersion. The photosensitive insulation paste is thickened and has a poor solubility in alkali as a result of crosslinking between an acidic functional group such as a carboxy group in the alkali-soluble polymer and polyvalent metal ions on the surface of the inorganic powder or polyvalent metal ions leaching from the inorganic powder into the paste. Thus, the photosensitive insulation paste is more easily thickened and more likely to have a poor solubility in alkali when the amount of polyvalent metal ions on the surface of the inorganic powder is larger or when polyvalent metal ions more easily leach out from the inorganic powder. How easily polyvalent metal ions leach out can be determined based on the conductivity when the inorganic powder of interest is dispersed in pure water. Use of the inorganic powder having a conductivity of 170 mS/m or less in the photosensitive insulation paste of the present disclosure makes it possible to prevent the photosensitive insulation paste from being thickened and becoming insoluble in an alkaline developer due to polyvalent metal ions. The conductivity is preferably 100 mS/m or less, more preferably 50 mS/m or less. At the same time, the conductivity is 0 mS/m or more, for example.

In the photosensitive insulation paste of the present disclosure, the inorganic powder containing an element that forms a polyvalent metal contains, on a surface thereof, the element that forms a polyvalent metal ion at a content of preferably less than 2.0 atom %. When the content of the element that forms a polyvalent metal ion on the surface of the inorganic powder is less than 2.0 atom %, adsorption of polyvalent metal ions on the surface of the inorganic powder onto the alkali-soluble polymer can be reduced, which can prevent an increase in the viscosity of the photosensitive insulation paste. More preferably, the content of the element that forms a polyvalent metal ion is less than 1.0 atom %. At the same time, the content of the element that forms a polyvalent metal ion may be 0 atom %. Herein, the content of the element that forms a polyvalent metal ion on the surface of the inorganic powder is a value qualified and quantified by X-ray photoelectron spectroscopy (XPS).

In the photosensitive insulation paste of the present disclosure, preferably, at least a portion of the surface of the inorganic powder containing an element that forms a polyvalent metal ion is covered with a ceramic coating. When at least a portion of the surface of the inorganic powder is covered with a ceramic coating having a high chemical stability, it makes it possible to reduce adsorption of the alkali-soluble polymer onto the inorganic powder and leaching of polyvalent metal ions from the inorganic powder. More preferably, the entire surface of the inorganic powder is covered with a ceramic coating.

Preferably, the ceramic coating mainly contains SiO₂, because SiO₂ has a high chemical stability and can prevent adsorption of the alkali-soluble polymer onto the inorganic powder and leaching of polyvalent metal ions from the inorganic powder. The ceramic coating may contain another element that forms a polyvalent metal ion in addition to SiO₂. Preferably, its concentration is lower in the ceramic coating than that inside the inorganic powder. SiO₂ as the main component of the ceramic coating accounts for preferably 95 mass % or more, more preferably 98 mass % or more, still more 99 mass % or more of the ceramic coating.

Preferably, the percentage of the ceramic coating is 2.5 wt % or more and 6.5 wt % or less (i.e., 2.5 wt % to 6.5 wt %) relative to the inorganic powder taken as 100 wt % in terms of SiO₂. When the percentage of the ceramic coating is less than 2.5 wt %, the effect of preventing adsorption of the alkali-soluble polymer onto the inorganic powder and the effect of preventing leaching of polyvalent metal ions may not be sufficient. When the percentage of the ceramic coating is more than 6.5 wt %, the effect of preventing adsorption of the alkali-soluble polymer onto the inorganic powder and the effect of preventing leaching of polyvalent metal ions will not be enhanced any more, which is economically unfavorable.

The ceramic coating may be a film containing an inorganic component such as SiO₂ and an organic substance, or it may be an organic-inorganic hybrid film. In particular, when the ceramic coating is an organic-inorganic hybrid film, the ceramic coating has a higher flexibility, so that cracking of the ceramic coating can be prevented. Examples of the organic substance include poly(2-methyloxazoline) having an amidocarbonyl group, poly(N,N-dimethylacrylamide) having an amidocarbonyl group, and polyvinylpyrrolidone (PVP) having an amidocarbonyl group. Preferably, the percentage of the organic substance in the ceramic coating is 0.01 wt % or more and 1.0 wt % or less (i.e., from 0.01 wt % to 1.0 wt %) relative to the inorganic powder taken as 100 wt % in terms of SiO₂.

In the photosensitive insulation paste of the present disclosure, the difference between a refractive index N1 of the ceramic coating and a refractive index N2 of a mixture of the alkali-soluble polymer, the photosensitive monomer, and the photoinitiator is as follows: |N1−N2|≤0.3. A large refractive index difference between the ceramic coating and the mixture of the alkali-soluble polymer, the photosensitive monomer, and the photoinitiator tends to cause scattering of irradiated light, which may result in thicker pattern lines and poor depth curability. A refractive index difference in the above range makes it possible to reduce scattering of irradiated light and improve the resolution. More preferably, the difference is as follows: |N1−N2|≤0.1; or may be as follows: |N1−N2|=0.

Examples of methods of covering the surface of the inorganic powder with a ceramic coating include various methods such as one in which the surface of the inorganic powder is covered with a separately prepared ceramic material; one in which the inorganic powder is oxidized to generate an oxide film of the inorganic powder on the surface; and one in which a solution that forms an oxide when heated or like is attached to a surface of the inorganic powder, and then heat treatment is performed under predetermined conditions so that the surface of the inorganic powder is coated with ceramic (e.g., sol-gel method). The sol-gel method is preferred because an organic-inorganic hybrid film can be easily formed.

Preferably, the photosensitive insulation paste of the present disclosure contains a filler (aggregate) in addition to the insulator mainly containing a metal oxide crystal and the amorphous insulator mainly containing SiO₂. The term “filler” as used herein refers to inorganic particles that are present in the form of particles without being softened even in a firing temperature range (e.g., 850° C. or higher and 950° C. or lower (i.e., from 850° C. to 950° C.)) of the photosensitive paste. Various ceramic materials can be used as the filler. Examples include crystalline fillers such as quartz, alumina, magnesia, spinel, silica, forsterite, steatite, and zirconia. One or a combination of two or more of these may be used as the filler. Use of the filler makes it possible to reduce the coefficient of thermal expansion of the insulation layer so as to avoid forming defects and breakage during firing. Preferred fillers are alumina and quartz. Alumina has a refractive index similar to that of the alkali-soluble polymer, and use of alumina results in an insulation layer having a good strength while achieving an excellent resolution. The refractive index of quartz is low and similar to that of the alkali-soluble polymer, which makes it possible to control the sinterability while maintaining the resolution. The crystallinity of quartz is not limited.

In the photosensitive insulation paste of the present disclosure, the particle size of the inorganic powder containing an element that forms a polyvalent metal ion and the particle size of the filler are preferably 0.1 μm or more and 5.0 μm or less (i.e., from 0.1 μm to 5.0 μm). The inorganic powder and the filler may not be easily dispersed in the paste when their particle sizes are less than 0.1 μm. The inorganic powder and the filler may distort the smoothness of the insulation layer and the shape of grooves that are formed after development, when their particle sizes are larger than 5.0 μm. More preferred particle sizes are 0.3 μm or more and 3.0 μm or less (i.e., from 0.3 μm to 3.0 μm). The particle sizes of the inorganic powder and the filler are values measured with a laser diffraction particle size distribution meter (LA960) available from Horiba, Ltd.

In the photosensitive insulation paste of the present disclosure, the total amount of the inorganic powder containing an element that forms a polyvalent metal ion and the filler is preferably 50 wt % or more and 80 wt % or less (i.e., from 50 wt % to 80 wt %), more preferably 60 wt % or more and 70 wt % or less (i.e., from 60 wt % to 70 wt %). Regarding the content percentages of the inorganic powder containing an element that forms a polyvalent metal ion and the filler, preferably, the content percentage of the inorganic powder is 40 wt % or more and 60 wt % or less (i.e., from 40 wt % to 60 wt %) when the total of the inorganic powder and the filler is taken as 100 wt %.

### (Alkali-Soluble Polymer)

A polymer that can be used as the alkali-soluble polymer may be, for example, an acrylic copolymer having a functional group such as a carboxy group in its side chain. Specific examples include a copolymer of an unsaturated carboxylic acid and an ethylenically unsaturated compound other than the unsaturated carboxylic acid. Examples of the unsaturated carboxylic acid include acrylic acid, methacrylic acid, maleic acid, fumaric acid, vinyl acetate, and acid anhydrides thereof. Examples of the ethylenically unsaturated compound other than the unsaturated carboxylic acid include unsaturated carboxylates. Specific examples include acrylates such as methyl acrylate and ethyl acrylate; methacrylates such as methyl methacrylate and ethyl methacrylate; and fumarates such as monoethyl fumarate.

The acrylic copolymer having a carboxy group in its side chain may be one in which an unsaturated bond is introduced therein as described below.

(1) To a carboxy group in a side chain of the acrylic copolymer is added an acrylic monomer having a functional group, such as an epoxy group, capable of reacting with the carboxy group.

(2) After the acrylic copolymer in which an epoxy group instead of a carboxy group is introduced in its side chain is reacted with an unsaturated monocarboxylic acid, a saturated or unsaturated polycarboxylic acid anhydride is further introduced into the acrylic copolymer.

Further, preferably, the acrylic copolymer having a carboxy group in its side chain has a weight average molecular weight (Mw) of 50000 or less and an acid value of 30 mgKOH/g or more and 150 mgKOH/g or less (i.e., from 30 mgKOH/g to 150 mgKOH/g).

The photosensitive monomer and the photoinitiator are not limited, and any known ones for use in photosensitive pastes can be used.

The total amount of the alkali-soluble polymer, photosensitive monomer, and photoinitiator in the photosensitive insulation paste of the present disclosure is preferably 25 wt % or more, more preferably 30 wt % or more, and is preferably 45 wt % or less, more preferably 35 wt % or less.

The photosensitive insulation paste of the present disclosure may further contain an organic solvent, an organic dye, and the like. Any known organic solvent and any known organic dye for use in photosensitive pastes can be used.

### Photosensitive Conductor Paste

Next, the case where the photosensitive paste of the present disclosure is a photosensitive conductor paste is described, mainly focusing on the difference from the photosensitive insulation paste described above.

Examples of the “element that forms a polyvalent metal ion” in the photosensitive conductor paste of the present disclosure are the same as those of the photosensitive insulation paste described above.

In the photosensitive conductor paste of the present disclosure, preferably, the inorganic powder containing an element that forms a polyvalent metal ion is a metal. The metal for use in the photosensitive conductor paste of the present disclosure is suitably a base metal, which has been conventionally a problem in terms of thickening of the photosensitive paste. The metal is preferably the element that forms a polyvalent metal ion, more preferably at least one element selected from the group consisting of alkaline earth metals, lanthanoids, Ni, Cu, Pd, Al, Ti, Zr, Zn, Ga, Pb, Nb, Fe, Co, and V, still more preferably Cu or Ni.

In the photosensitive conductor paste of the present disclosure, the inorganic powder containing an element that forms a polyvalent metal contains the element that forms a polyvalent metal ion at a content of preferably 0.01 mass % or more, more preferably 0.1 mass % or more. The content may be 100 mass %.

In the photosensitive conductor paste of the present disclosure, when the inorganic powder containing an element that forms a polyvalent metal ion is a metal, the photosensitive conductor paste may contain two or more metals in one inorganic powder or may contain two or more inorganic powders each containing one metal in which the metal type is different among the inorganic powders. When the photosensitive conductor paste contains two or more inorganic powders each containing one metal in which the metal type is different among the inorganic powders, the metals different from each other react with each other to form an alloy when the photosensitive conductor paste is fired. When two or more metals are used in the photosensitive conductor paste of the present disclosure, use of two or more inorganic powders each containing one metal in which the metal type is different among the inorganic powders is preferred.

The photosensitive conductor paste of the present disclosure may contain a bonding agent in addition to the inorganic powder containing an element that forms a polyvalent metal ion. Non-limiting examples of the bonding agent include SiO₂—B₂O₃—Bi₂O₃-based glass powder. In the photosensitive conductor paste of the present disclosure, the total amount of the inorganic powder containing an element that forms a polyvalent metal ion is preferably 60 wt % or more and 85 wt % or less (i.e., from 60 wt % to 85 wt %), more preferably 65 wt % or more and 80 wt % or less (i.e., from 65 wt % to 80 wt %).

In the photosensitive conductor paste of the present disclosure, the particle sizes of the inorganic powder containing an element that forms a polyvalent metal ion and the bonding agent are preferably 0.1 μm or more and 5.0 μm or less (i.e., from 0.1 μm to 5.0 μm). The particle sizes of the inorganic powder and the bonding agent can be measured by the method described above for the photosensitive insulation paste.

In the photosensitive conductor paste of the present disclosure, the conductivity of the inorganic powder containing an element that forms a polyvalent metal ion and the content of the element that forms a polyvalent metal ion on the surface of the inorganic powder containing the element that forms a polyvalent metal ion are the same as those of the photosensitive insulation paste. In the photosensitive conductor paste of the present disclosure, preferably, at least a portion of the surface of the inorganic powder containing an element that forms a polyvalent metal ion is covered with a ceramic coating. Embodiments and properties such as the composition of the ceramic coating are as described above for the photosensitive insulation paste.

The types and embodiments of the alkali-soluble polymer, photosensitive monomer, photoinitiator, organic solvent, and organic dye contained in the photosensitive conductor paste of the present disclosure are as described above for the photosensitive insulation paste. The total amount of the alkali-soluble polymer, photosensitive monomer, and photoinitiator in the photosensitive conductor paste of the present disclosure is preferably 10 wt % or more, more preferably 15 wt % or more, and is also preferably 35 wt % or less, more preferably 20 wt % or less.

### Method of Producing Electronic Component

The method of producing electronic components of the present disclosure includes a first method of producing electronic components or a second method of producing electronic components. The first method of producing electronic components of the present disclosure includes: forming an insulation layer with an insulation paste; and forming a conductor layer with a conductor paste on the insulation layer, wherein the insulation paste is the photosensitive insulation paste of the present disclosure.

Hereinafter, an example of the first method of producing electronic components of the present disclosure is described.

First, an insulation paste layer having a desired thickness is formed by repeatedly coating with the photosensitive insulation paste of the present disclosure by screen printing. The insulation paste layer is an insulation layer for an outer layer, which is located outward of the conductor layer.

Grooves of internal electrode patterns are formed by photolithography in the insulation paste layer formed above.

Then, the insulation paste layer including the grooves of the internal electrode patterns is coated and filled with a conductor paste to form a conductor paste layer on the insulation paste layer, and photolithography is performed for patterning to provide a conductor layer having a desired shape. Thus, the conductor paste layer that serves as an internal electrode is formed on the insulation paste layer. At this point, a desired coil pattern can be drawn on a photomask. Any conductor paste may be used in the first method of producing electronic components of the present disclosure. For example, a known Ag paste or the like can be used, or the photosensitive conductor paste of the present disclosure may be used.

Then, the conductor paste layer is coated with the photosensitive insulation paste of the present disclosure to form an insulation paste layer that serves as an internal insulation layer, and unnecessary parts are removed by photolithography, followed by coating and filling with a conductor paste, whereby a conductor paste layer is formed.

The above steps are repeated as many times as necessary, whereby a paste laminate is formed which includes the insulation layer for an outer layer, the insulation paste layer that serves as an internal insulation layer, and the conductor paste layer.

Lastly, the paste laminate is repeatedly coated with the insulation paste by screen printing to form an insulation paste layer. The insulation paste layer is an insulation layer for an outer layer, which is located outward of the conductor layer.

A mother laminate is obtained by the above steps.

The thus-obtained mother laminate is cut by dicing or the like to obtain multiple raw laminates. The cut raw laminates are fired at 850° C. or higher and 950° C. or lower (i.e., from 850° ° C. to 950° C.) to obtain fired laminates. The thus-obtained fired laminates are subjected to barrel polishing or plating as needed.

Electronic components are completed by the above steps.

The second method of producing electronic components of the present disclosure includes: forming an insulation layer with an insulation paste; and forming a conductor layer with a conductor paste on the insulation layer, wherein the conductor paste is the photosensitive conductor paste of the present disclosure.

The second method of producing electronic components of the present disclosure can be similarly performed by the method described as an example of the first method of producing electronic components. A known insulation paste can be used in the second method of producing electronic components. For example, a known photosensitive glass paste can be used. The conductor layer is formed with the photosensitive conductor paste of the present disclosure.

### EXAMPLES

Examples that more specifically disclose the present disclosure are described below. The present disclosure is not limited to these Examples.

### Photosensitive Paste

### (Sol-Gel Coating on Inorganic Powder)

Glass frit mainly containing SiO₂—B₂O₃—Al₂O₃—CaO and having an average particle size of 1.0 μm, a softening point (Ts) of 800° C., and a crystallization point (Tc) of 890° C. was used as a glass powder containing an element that forms a polyvalent metal ion and having a crystallization point. This glass frit (20 g) was added to ethanol (37.2 g). Next, tetraethoxysilane (TEOS) was weighed out in an amount of 3 wt % or 6 wt % in terms of SiO₂ relative to the glass frit taken as 100 wt % and was added to the ethanol containing the glass frit, followed by stirring. Thus, samples with different TEOS concentrations were prepared. Further, polyvinylpyrrolidone (PVP) was weighed out in an amount of 0.1 wt % relative to the glass frit taken as 100 wt % and dissolved in pure water (3.2 g). The solution was added dropwise to the ethanol containing the glass frit and 3 wt % TEOS or the ethanol containing the glass frit and 6 wt % TEOS, followed by stirring and mixing for 60 minutes. Thus, glass frit coated with TEOS or TEOS and PVP and having a ceramic coating thereon was formed.

As a comparative example, malonic acid was added instead of TEOS and PVP to form glass frit having a malonic acid coating formed on its surface.

### (Preparation of Photosensitive Paste)

Materials were blended in the percentages described below to produce a photosensitive paste. Specifically, the materials were weighed out, and the weighed-out materials were stirred in a planetary mixer for 30 minutes, followed by kneading by passing through a triple roll mill four times, whereby a photosensitive paste was produced. As a comparative example, a photosensitive paste was produced using uncoated glass frit instead of the coated glass frit.

### <Organic Component>

Alkali-soluble polymer: copolymer of methacrylic acid and methyl methacrylate, 24.7 parts by weight
Photosensitive monomer: trimethylolpropane triacrylate, 8.2 parts by weight
Solvent: pentamethylene glycol, 2.6 parts by weight
Photoinitiator (1): 2-methyl-1-[4-(methylthio)phenyl]-2-morpholinopropan-1-one, 0.4 parts by weight
Photoinitiator (2): 2,4-diethylthioxanthone, 0.2 parts by weight
Photoinitiator (3): bis(2,4,6-trimethylbenzoyl)phenylphosphine oxide, 0.7 parts by weight
Yellow dye: oil yellow 129 (product name, available from Orient Chemical Industries Co., Ltd.), 0.2 parts by weight

### <Inorganic Component>

### Inorganic Powder Mixture, 63 Parts by Weight in Total

The inorganic powder mixture was prepared by blending the coated glass frit, alumina, and quartz at a volume ratio of 50:20:30.

The mixture of the alkali-soluble polymer, photosensitive monomer, and photoinitiators (1) to (3) had a refractive index of about 1.5. The ceramic coating containing 3 wt % TEOS had a refractive index of 1.55. The ceramic coating containing 3 wt % TEOS and PVP had a refractive index of 1.50 or more and 1.80 or less (i.e., from 1.50 to 1.80). The ceramic coating containing 6 wt % TEOS and PVP had a refractive index of 1.50 or more and 1.80 or less (i.e., from 1.50 to 1.80).

### Evaluation of Inorganic Powder

### (Measurement and Evaluation of Conductivity)

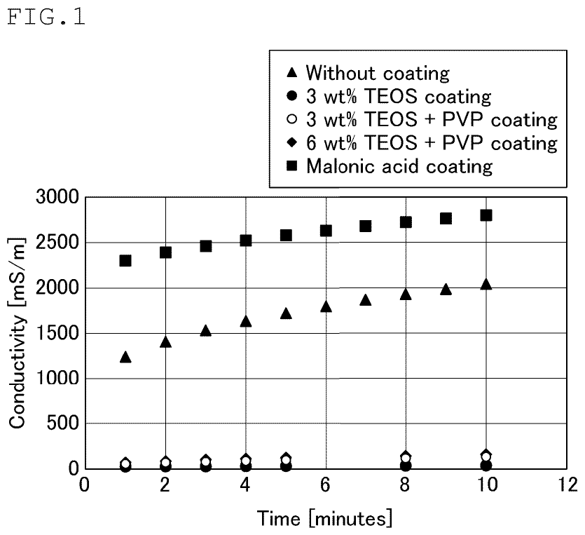

The TEOS-coated glass frit (1 g) or the TEOS- and PVP-coated glass frit (1 g) was added to pure water (100 g), followed by stirring with a spatula for about 60 seconds, whereby a dispersion of 1 wt % glass frit was produced. The conductivity of the dispersion was measured with a conductivity meter (D-54, 355-10D available from Horiba, Ltd.). The conductivity of the dispersion was measured at one minute interval until five minutes after addition of the glass frit. Thereafter, the conductivity of the dispersion was measured at 8 minutes and 10 minutes after addition. The conductivity of the uncoated glass frit (without coating) and the conductivity of the glass frit having a surface coated with malonic acid (malonic acid coating) were similarly measured. FIG. 1 shows the results.

FIG. 1 is a graph showing the conductivity of a dispersion of 1 wt % of the inorganic powder in pure water. As shown in FIG. 1, the TEOS-coated glass frit and the TEOS- and PVP-coated glass frit each had a low conductivity, i.e., 170 mS/m or less, for a duration of 10 minutes immediately after dispersion. The uncoated glass frit (without coating) and the malonic acid-coated glass frit (malonic acid coating) had a high conductivity, i.e., 1200 mS/m or more, at 10 minutes immediately after dispersion. The coated glass frit having the lowest conductivity was the coated glass frit coated with only TEOS.

### (Measurement of Elemental Composition of Surface of Inorganic Powder)

The elemental composition of the surface of the glass frit before and after coating was measured and analyzed by X-ray photoelectron spectroscopy (XPS). Table 1 shows the results.
Device: VersaProbe available from ULVAC-PHI, Inc.
Measurement area: 100 μm ϕ
Analysis depth: several nanometers

TABLE 1

| | Elemental Composition of Surface | | | | | | |
|---|---|---|---|---|---|---|---|
| | (atom %) | | | | | | |
| Sample | B | C | N | O | Al | Si | Ca |
| Without coating | 4 | 23 | — | 51 | 2 | 10 | 9 |
| 3 wt % TEOS | — | 38 | 3 | 43 | — | 15 | <1 |
| 3 wt % TEOS + PVP | — | 24 | — | 55 | — | 21 | <1 |
| 6 wt % TEOS + PVP | — | 28 | 3 | 49 | — | 19 | 1 |

The values in Table 1 are not absolute values. Calculation was performed such that the sum of the total composition would be 100 atom %.

The “-” in Table 1 indicates values below the detection limit.

The description of atoms in trace amounts are omitted in Table 1, so that there are cases where the sum does not add up to 100 atom %.

As shown in Table 1, the content of Ca, which is an element that forms a polyvalent metal ion, was 9 atom % on the surface of the uncoated glass frit (without coating), while the content of Ca was 1 atom % or less in the coated glass frit.

### Evaluation of Photosensitive Paste

### (Viscosity Measurement)

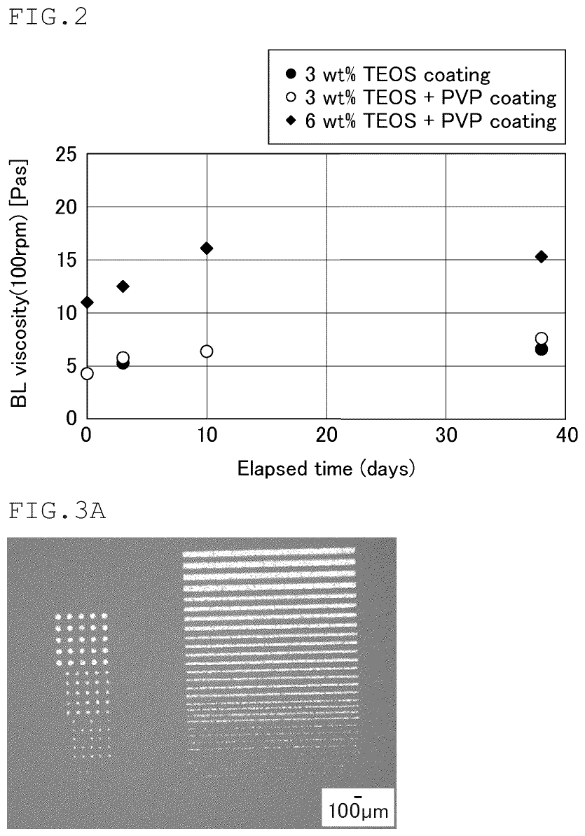

The viscosity of the photosensitive paste was measured with a Brookfield viscometer (BF viscometer) at a rotating speed of 100 rpm and a temperature of 25° C. The measurement was performed immediately after preparation of the photosensitive paste (at day 0), at day 3, at day 10, and at day 38. FIG. 2 shows the results.

FIG. 2 is a graph showing measurement results of the BF viscosity of the photosensitive pastes produced in Examples. As shown in FIG. 2, the coated-glass-frit-containing photosensitive pastes each showed a gradual increase in the viscosity from the time of preparation until 10 days after preparation, but hardly showed an increase in the viscosity thereafter. These photosensitive pastes were applicable for screen printing or the like even 38 days after preparation. In contrast, the uncoated-glass-frit-containing photosensitive paste was gelled immediately after kneading with an organic component, so that the viscosity could not be measured. The viscosity was relatively low in the photosensitive paste containing the glass frit coated with 3 wt % TEOS and the photosensitive paste containing the glass frit coated with 3 wt % TEOS and PVP, among the coated-glass-frit-containing photosensitive pastes.

### (Developability)

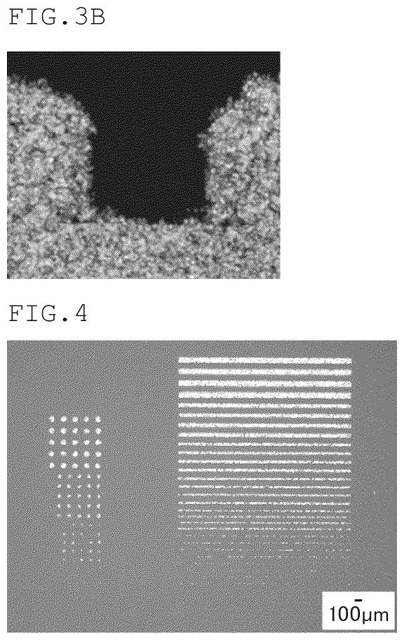

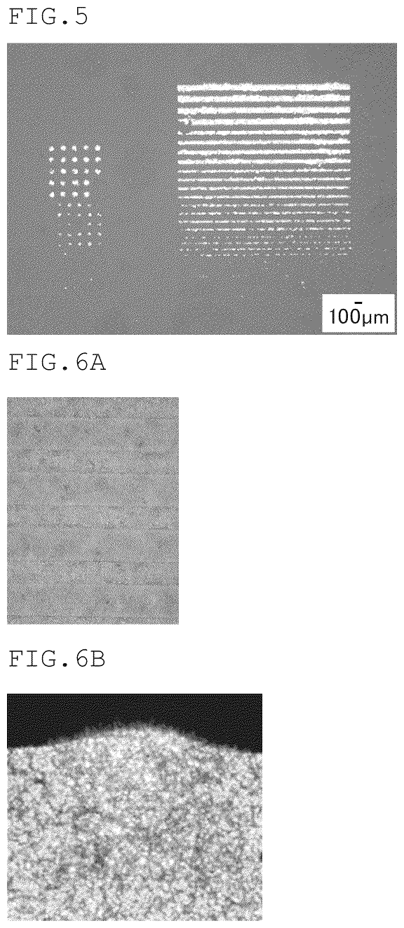

The coated-glass-frit-containing photosensitive pastes were each printed to a thickness of 20 μm by screen printing and dried in a safety oven, followed by exposure via a photomask having openings of various sizes and development with an alkaline aqueous solution, whereby patterns were formed. Patterns were similarly formed with the photosensitive paste containing the glass frit having a surface coated with malonic acid. FIG. 3A, FIG. 3B, FIG. 4, FIG. 5, FIG. 6A, and FIG. 6B show the results.

FIG. 3A is a photo showing planar shapes of various patterns formed by photolithography with the photosensitive paste containing glass frit coated with 3 wt % TEO. FIG. 3B is a photo showing a cross-sectional shape of a portion of the patterns in FIG. 3A.

FIG. 4 is a photo showing planar shapes of various patterns formed by photolithography with the photosensitive paste containing glass frit coated with 3 wt % TEO and PVP.

FIG. 5 is a photo showing planar shapes of various patterns formed by photolithography with the photosensitive paste containing glass frit coated with 6 wt % TEO and PVP.

FIG. 6A is a photo showing planar shapes of various patterns formed by photolithography with the photosensitive paste containing glass frit having a surface coated with malonic acid. FIG. 6B is a photo showing a cross-sectional shape of a portion of the patterns in FIG. 6A.

As shown in FIG. 3A, FIG. 3B, FIG. 4, and FIG. 5, the photosensitive paste containing the TEOS- or TEOS- and PVP-coated glass frit dissolved in the alkaline aqueous solution and formed grooves. In contrast, as shown in FIG. 6A and FIG. 6B, in the case of the photosensitive paste containing the glass frit having a surface coated with malonic acid, the unexposed portion did not dissolve in the alkaline aqueous solution but swelled, failing to form grooves.

What is claimed is:

1. A photosensitive paste comprising:
an inorganic powder containing an element capable of forming a polyvalent metal ion;
an alkali-soluble polymer;
a photosensitive monomer; and
a photoinitiator,
wherein a dispersion of 1 wt % of the inorganic powder in pure water has a conductivity of 170 mS/m or less at 10 minutes after dispersion.

2. The photosensitive paste according to claim 1, wherein
the inorganic powder contains, on a surface thereof, the element at a content of less than 2.0 atom %.

3. The photosensitive paste according to claim 1, wherein
at least a portion of a surface of the inorganic powder is covered with a ceramic coating.

4. The photosensitive paste according to claim 3, wherein the ceramic coating mainly contains SiO₂.

5. The photosensitive paste according to claim 3, wherein
a difference between a refractive index N1 of the ceramic coating and a refractive index N2 of a mixture of the alkali-soluble polymer, the photosensitive monomer, and the photoinitiator is as follows: |N1−N2|≤0.3.

6. The photosensitive paste according to claim 1, wherein
the inorganic powder is an insulator mainly containing a metal oxide crystal or an amorphous insulator mainly containing SiO₂.

7. The photosensitive paste according to claim 6, wherein
the element is at least one element selected from the group consisting of alkaline earth metals, lanthanoids, Ni, Cu, Pd, Al, Ti, Zr, Zn, Ga, Pb, Nb, Fe, Co, and V.

8. The photosensitive paste according to claim 6, wherein
the inorganic powder is a glass powder having a crystallization point.

9. The photosensitive paste according to claim 1, wherein
the inorganic powder is a metal.

10. The photosensitive paste according to claim 9, wherein
the metal is a base metal.

11. The photosensitive paste according to claim 9, wherein
the metal is at least one element selected from the group consisting of alkaline earth metals, lanthanoids, Ni, Cu, Pd, Al, Ti, Zr, Zn, Ga, Pb, Nb, Fe, Co, and V.

12. The photosensitive paste according to claim 9, wherein
the metal contains Cu or Ni.

13. A method of producing electronic components, the method comprising:
forming an insulation layer with an insulation paste; and
forming a conductor layer with a conductor paste on the insulation layer,
wherein the insulation paste is the photosensitive paste according to claim 6.

14. The method of producing electronic components according to claim 13, wherein
the conductor paste comprises:
an inorganic powder containing an element capable of forming a polyvalent metal ion;
an alkali-soluble polymer;
a photosensitive monomer; and
a photoinitiator,
wherein a dispersion of 1 wt % of the inorganic powder in pure water has a conductivity of 170 mS/m or less at 10 minutes after dispersion, and
the inorganic powder is a metal.

15. A method of producing electronic components, the method comprising:
forming an insulation layer with an insulation paste; and
forming a conductor layer with a conductor paste on the insulation layer,
wherein the conductor paste is the photosensitive paste according to claim 9.

16. The photosensitive paste according to claim 2, wherein
at least a portion of the surface of the inorganic powder is covered with a ceramic coating.

17. The photosensitive paste according to claim 4, wherein
a difference between a refractive index N1 of the ceramic coating and a refractive index N2 of a mixture of the alkali-soluble polymer, the photosensitive monomer, and the photoinitiator is as follows: |N1−N2|≤0.3.

18. The photosensitive paste according to claim 2, wherein
the inorganic powder is an insulator mainly containing a metal oxide crystal or an amorphous insulator mainly containing SiO₂.

19. The photosensitive paste according to claim 7, wherein
The inorganic powder is a glass powder having a crystallization point.

20. The photosensitive paste according to claim 2, wherein
the inorganic powder is a metal.
